(19) United States
(12) Patent Application Publication
(10) Pub. No.: US 2007/0051991 A1
(43) Pub. Date: Mar. 8, 2007

(54) CMOS image sensor and method for fabricating the same

(76) Inventor: Han Chang Hun, Icheon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/507,994

(22) Filed: Aug. 22, 2006

(30) Foreign Application Priority Data
Aug. 23, 2005 (KR) 10-2005-0077201

(51) Int. Cl. H01L 31/062; H01L 21/00

(52) U.S. Cl. 257/294; 438/70; 257/E31.121

(57) ABSTRACT

Provided are a CMOS image sensor and a method for fabricating the same. The CMOS image sensor including: a metal pad formed on a pad region of a substrate; an insulation layer formed on the entire surface of the substrate, and having a metal pad opening part to expose a predetermined portion of the surface of the metal pad; a plurality of first microlenses formed a predetermined distance from each other above the insulation layer in a unit pixel region of the substrate; and a plurality of second microlenses formed on the entire surface of the unit pixel region including the first microlenses.

### RELATED APPLICATION

This application claims the benefit under 35 U.S.C. §119(e) of Korean Patent Application Number 10-2005-0077201 filed Aug. 23, 2005, which is incorporated herein by reference in its entirety.

### FIELD OF THE INVENTION

The present invention relates to an image sensor, and more particularly, to a CMOS image sensor with an improved ability of concentrating light in a microlens, and a method for fabricating the same.

### BACKGROUND OF THE INVENTION

An image sensor is a semiconductor device that converts an optical image into electric signals. Examples of an image sensor include a charge coupled device (CCD) and a complementary metal oxide semiconductor (CMOS) image sensor.

Nowadays, to overcome drawbacks of the CCD, the CMOS image sensor is widely used as a next-generation image sensor.

In the CMOS image sensor, MOS transistors corresponding to the number of unit pixels are formed in a semiconductor substrate by using a CMOS technology. In the CMOS technology, a control circuit and a signal processing circuit are used as peripheral circuits. Additionally, the CMOS image sensor is a device employing a switching method. In the switching method, the MOS transistors sequentially detect the output of each unit pixel.

That is, the CMOS image sensor includes photodiodes and MOS transistors in the unit pixel, and sequentially detects an electric signal of each unit pixel to display an image.

Since the CMOS image sensor uses the CMOS technology, there are advantages of low power consumption and the small number of photolithography processes.

Moreover, the CMOS image sensor is widely used in application devices such as digital still cameras, and digital video cameras.

In addition, the CMOS image censor is classified into various types such as a 3T-type, a 4T-type, and 5T-type according to the number of transistors. For example, the 4T-type includes one photodiode and four transistors. An equivalent circuit and a layout for a unit pixel in the 3T-type CMOS image sensor will be described below.

FIG. 1 is a view of an equivalent circuit for a 3T-type CMOS image sensor. FIG. 2 is a view of a layout illustrating a unit pixel of the 3T-type CMOS image sensor.

The unit pixel of the 3T CMOS image sensor includes one photodiode PD, and three nMOS transistors T1, T2, and T3. The cathode of the photodiode PD is connected to a drain of the first nMOS transistor T1 and a gate of the second nMOS transistor T2.

Sources of the first and second nMOS transistors T1 and T2 are connected to a power line that supplies a reference voltage VR, and the gate of the first nMOS transistor T1 is connected to a reset line that supplies a reset signal RST.

Moreover, the source of the third nMOS transistor T3 is connected to the drain of the second nMOS transistor T2, and the drain of the third nMOS transistor T3 is connected to a readout circuit (not shown) through a signal line. Additionally, the gate of the third nMOS transistor T3 is connected to a column selection line that supplies a select signal SLCT.

Accordingly, the first nMOS transistor T1, the second nMOS transistor T2, and the third nMOS transistor T3 are called a reset transistor Rx, a drive transistor Dx, and a select transistor Sx, respectively.

In the unit pixel of a the 3T-type CMOS image sensor, as illustrated in FIG. 2, an active region 10 is defined and one photodiode 20 is formed on a broader width of the active region 10. Each of gate electrodes 120, 130, and 140 are formed on the rest of the active region 10 and overlap the narrower width of the active region 10 to form the three transistors T1, T2, T3, respectively.

That is, the reset transistor Rx is formed by using the gate electrode 120; the drive transistor Dx is formed by using the gate electrode 130; and the select transistor Sx is formed by using the gate electrode 140.

Impurity ion is implanted in the active region 10 except for below the gate electrodes 120, 130, and 140 such that source and drain regions of each transistor is formed.

Accordingly, a power supply voltage Vdd line is connected to the source and drain regions between the reset transistor Rx and the drive transistor Dx, and the source and drain regions in one side of the select transistor Sx are connected to the readout circuit (not shown).

Each of the gate electrodes 120, 130, and 140 are connected to each signal line, and each of the signal lines have a pad at the end to be connected to an external drive circuit (not shown).

Each signal line having a pad and next processes will be described.

FIGS. 3A to 3D are sectional views illustrating a method for fabricating a CMOS image censor according to the related art.

As illustrated in FIG. 3A, an insulation layer 101 (e.g., an oxide layer) such as a gate insulation layer and an interlayer insulation layer is formed on a semiconductor substrate 100 having a unit pixel region and a pad region. A metal pad 102 for each signal line is formed on the insulation layer 101 in the pad region of the semiconductor substrate 100.

The metal pad 102, as illustrated in FIG. 2, can be formed on a layer and of a material identical to that of the gate electrodes 120, 130, and 140. Additionally, the metal pad 102 can be formed of other material through an additional contact. Typically, the other material is aluminum (Al).

Then, an UV ozone process and a solution compositing process are performed on the surface of the metal pad 102 to increase a corrosion resistance of the metal pad 102 formed of Al.

After the metal pad 102 is formed on the pad region of the semiconductor substrate 100, a color filter layer (not shown) and microlenses are formed on the unit pixel region.

Typically, an oxide layer 103 is formed on the entire surface of the semiconductor substrate 100 having the metal pad 102, and a chemical mechanical planarization (CMP) process is performed on the entire surface of the oxide layer 103.

Next, through a photo and etching process, the oxide layer 103 is selectively removed to expose a predetermined portion of the surface of the metal pad 102 such that a metal pad opening part 104 is formed.

As illustrated in FIG. 3B, a nitride layer 105 for passivation is formed on the semiconductor substrate 100 including the metal pad opening part 104.

Then, as illustrated in FIG. 3C, after a sacrificial microlens layer is applied on the nitride layer 105, the sacrificial microlens layer is selectively patterned by using exposing and developing processes, and a sacrificial microlens 106 in a half-spherical shape is formed by performing a reflow process at a predetermined temperature.

As illustrated in FIG. 3D, an etching process is performed on the entire surface and the sacrificial microlens to form microlenses 107 spaced a predetermined distance apart from each other on the oxide layer 103.

Specifically, the sacrificial microlens 106 is etched by the etching process, and the exposed nitride layer 105 is etched at the same time. Consequently, the nitride layer 105 formed below the sacrificial microlens 106 remains such that a half-spherical microlens 107 is formed.

During this etching process, the nitride layer 105 formed on the pad region is removed to expose a metal pad opening part 104.

A method for fabricating the related art CMOS image censor has the following problems.

That is, when a microlens is formed using the sacrificial microlens as an etching mask, a gap between the microlenses occurs. The gap diminishes the ability of concentrating light. Therefore, it is difficult for semiconductor industries to meet the demand of reducing a chip size.

### SUMMARY OF THE INVENTION

Accordingly, the present invention is directed to a CMOS image sensor and a method for fabricating the same that addresses and/or substantially obviates one or more problems, limitations, and/or disadvantages of the related art.

An object of the present invention is to provide a CMOS image sensor with an improved ability of concentrating light in a microlens by removing the gap between microlens, and a method for fabricating the same.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a CMOS image sensor including: a metal pad formed on a pad region of a substrate; an insulation layer formed on an entire surface of the substrate, and having a metal pad opening part to expose a predetermined portion of the surface of the metal pad; a plurality of first microlenses formed a predetermined distance from each other above the insulation layer of the unit pixel region; and a plurality of second microlenses formed on an entire surface of the unit pixel region including the first microlenses.

In another aspect of the present invention, there is provided a method of fabricating a CMOS image sensor, the method including: forming a metal pad on a pad region of a substrate; forming an insulation layer on an entire surface of the substrate including the metal pad; forming a first microlens material layer above the insulation layer; forming sacrificial microlenses spaced a predetermined distance from each other on the first microlens material layer in a unit pixel region of the substrate; etching a surface of the resulting structure to form a plurality of first microlenses above the insulation layer of the unit pixel region; forming a second microlens material layer on an entire surface of the substrate including the first microlens; and selectively removing the second microlens material layer to expose a predetermined portion of the metal pad such that a metal pad opening part is formed.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a view of an equivalent circuit in a related art 3T-type CMOS image sensor;

FIG. 2 is a view of a layout illustrating a unit pixel of a related art 3T-type CMOS image sensor;

FIGS. 3A to 3D are sectional views illustrating a method for fabricating a CMOS image censor according to the related art;

FIG. 4 is a sectional view of a CMOS image sensor according to an embodiment of the present invention; and

FIGS. 5A to 5F are sectional views illustrating a method for fabricating a CMOS image censor according to an embodiment of the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

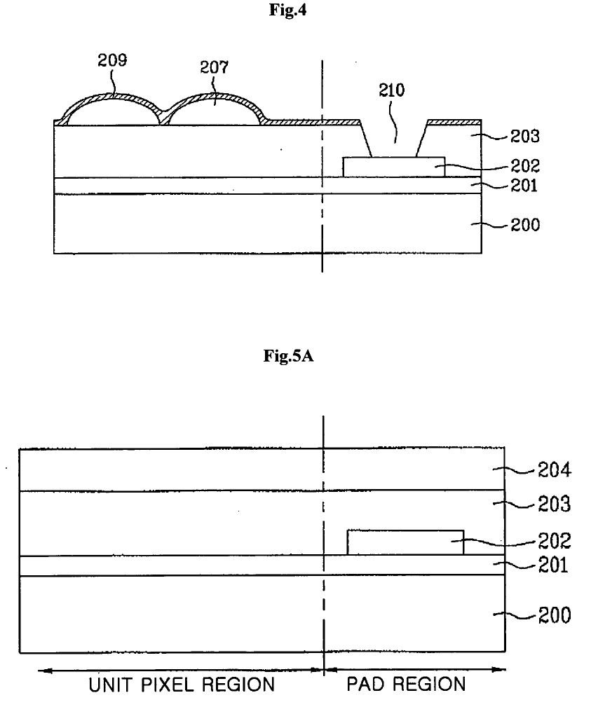

FIG. 4 is a sectional view of a CMOS image sensor according to an embodiment of the present invention.

As illustrated in FIG. 4, the CMOS image sensor includes an insulation layer 201, a metal pad 202, an oxide layer 203, a plurality of first microlenses 207, and a plurality of second microlenses 208. The insulation layer 201 can be formed on a semiconductor substrate 200 that is divided into a unit pixel region and a pad region. The metal pad 202 can be formed on the insulation layer 201 of the pad region. The oxide layer 203 can be formed on an entire surface of the semiconductor substrate 200, and includes a metal pad opening part 210 exposing a predetermined portion of the metal pad 202. The plurality of first microlenses 207 can be formed spaced a predetermined distance apart above the oxide layer 203 of the unit pixel region. The plurality of second microlenses 208 can be formed on an entire surface of the unit pixel region including the plurality of first microlenses 207.

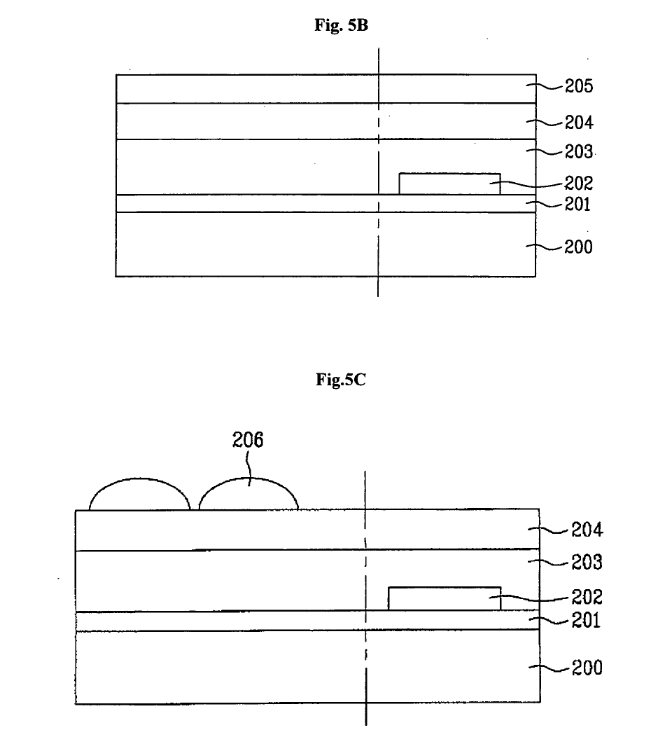

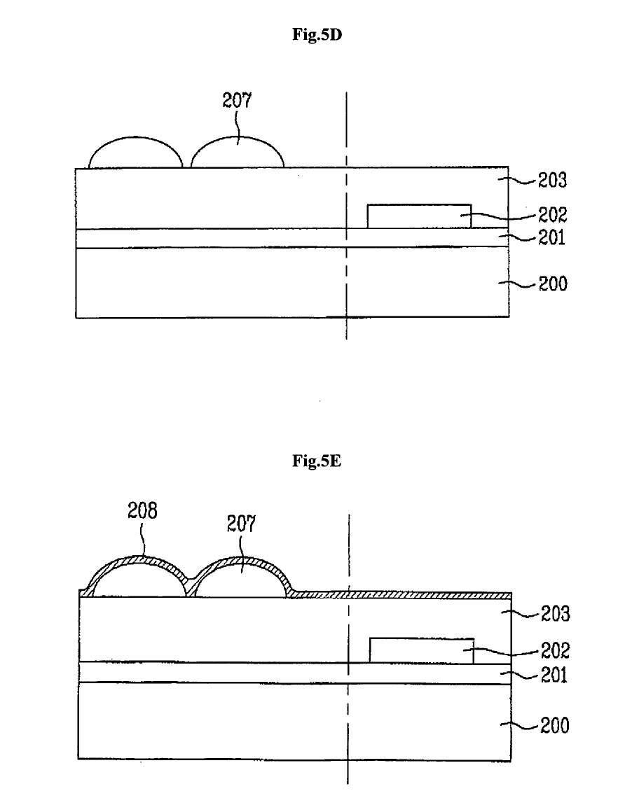

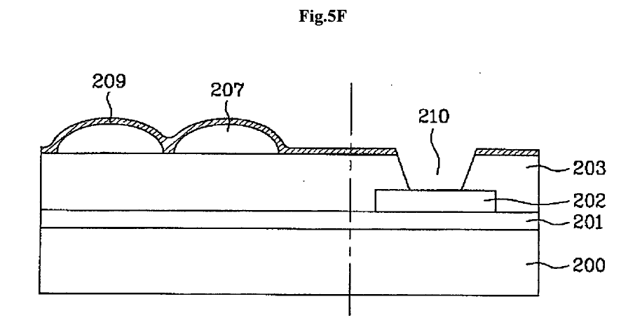

FIGS. 5A to 5F are sectional views illustrating a method for fabricating a CMOS image censor according to an embodiment of the present invention.

As illustrated in FIG. 5A, an insulation layer 201 can be formed on a semiconductor substrate 200. The insulation layer 201 can be a gate insulation layer and/or an interlayer insulation layer. In one embodiment, the insulation layer 201 can be an oxide layer. The semiconductor substrate can incorporate a unit pixel region and a pad region. A pad 202 for each signal line can be formed on the insulation layer 201 in the pad region of the semiconductor substrate 200.

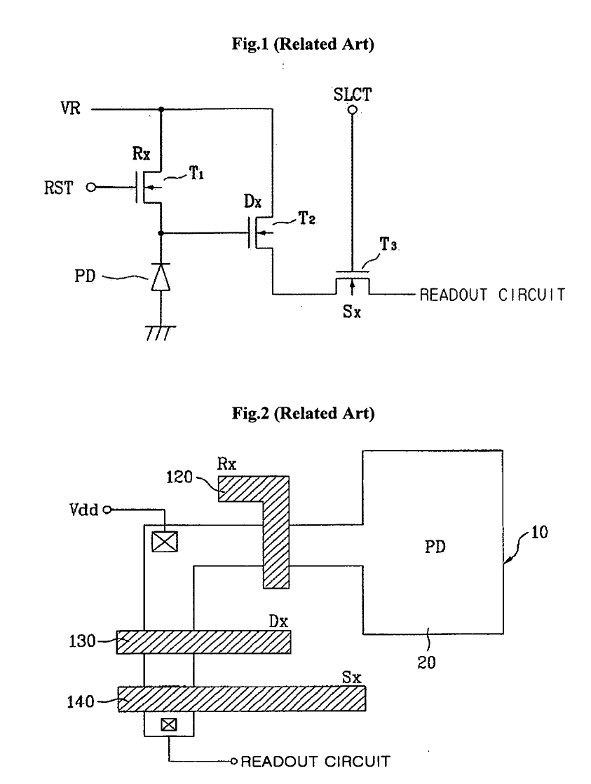

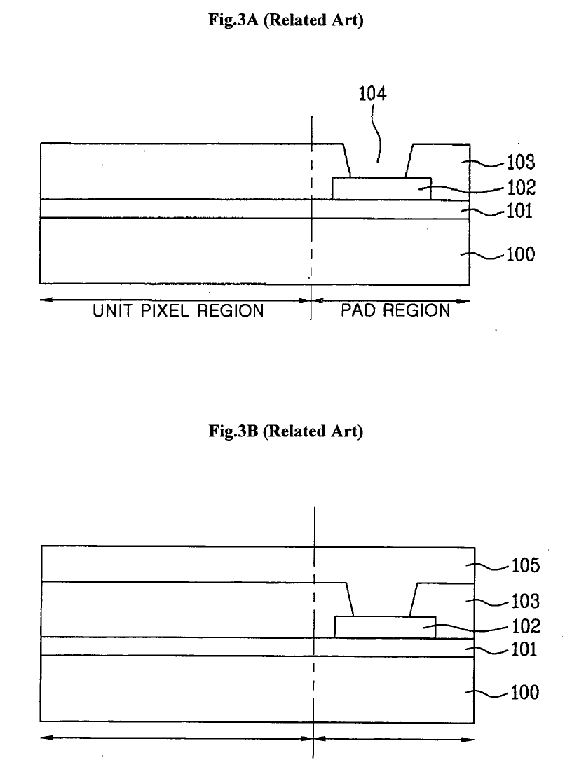

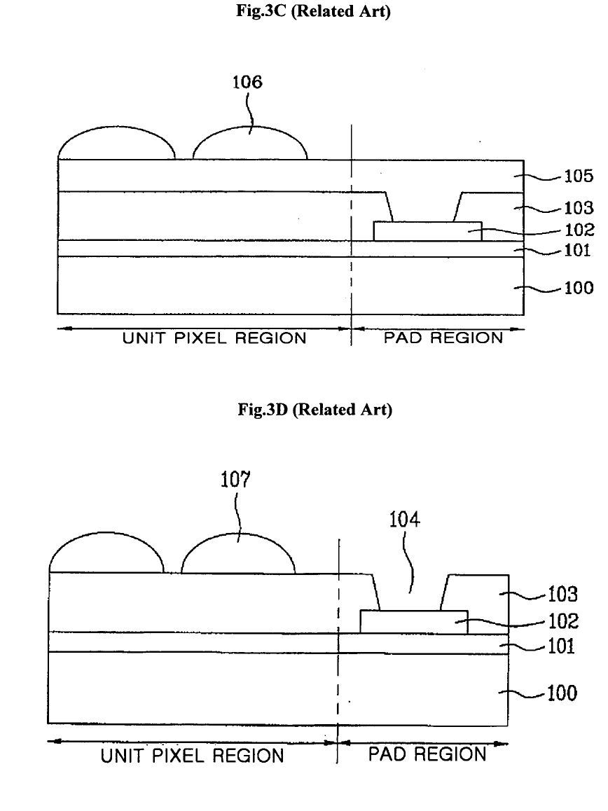

In a specific embodiment, the metal pad 202, as illustrated in FIG. 1, can be formed of the same material and on a layer identical to that of the gate electrodes 120, 130, and 140. The metal pad 202 can be formed of a further material through an additional contact. In one embodiment, the further material can be aluminum (Al).

For an aluminum metal pad, an UV ozone process and a solution compositing process can be performed to increase the corrosion resistance of the metal pad 202 formed of the Al.

After the metal pad 202 is formed on the pad region of the semiconductor substrate 200, a color filter layer (not shown) and microlens can be formed on the unit pixel region.

In one embodiment, an oxide layer 203 can be formed on the entire surface of the semiconductor substrate 200 including the metal pad 202. Then, a chemical mechanical planarization (CMP) can be performed on the entire surface of the oxide layer 203.

A first microlens material layer 204 can be formed above the planarized oxide layer 203.

In a specific embodiment, the first microlens material layer 204 can be formed of a nitride layer. The nitride layer can have a thickness of 1000 to 4000 Å and can serve as a passivation layer.

In a further embodiment, an additional nitride layer for planarization (not shown) can be formed below the first microlens material layer 204.

As illustrated in FIG. 5B, a sacrificial microlens material layer 205 can be formed on the first microlens material layer 204.

As illustrated in FIG. 5C, the sacrificial microlens material layer 205 can be selectively patterned by using an exposing and developing process. Then, a half-spherical shaped sacrificial microlens 206 can be formed by performing a reflow process at a predetermined temperature.

As illustrated in FIG. 5D, an etching process can be performed on the entire surface including the sacrificial microlens 206 to form the first microlens 207 above the oxide layer 203 in the unit pixel region. The first microlenses 207 can be separated a predetermined distance from each other.

In particular, the first microlens material layer 204 can be exposed and etched when the sacrificial microlens 206 is etched through the entire etching process. Consequently, the first microlens material layer 204 remains below the sacrificial microlens 206 to form the half-spherical shaped microlens 207.

The first microlens material layer 204 on the pad region can be removed during the etching process.

In a specific embodiment, the entire etching process can be performed with an etching selectivity of the sacrificial microlens 206 and the first microlens material layer 204 being 1:1.

As illustrated in FIG. 5E, a second microlens material layer 208 can be formed on the entire surface of the semiconductor substrate 200 including the first microlens 207.

In one embodiment, the second microlens material layer 208 can be formed at a thickness that is a half of the distance between the adjacent first microlenses 207.

The second microlens material layer 208 can be selected to have transmittance of 80% or higher. In a specific embodiment, the second microlens material layer 208 can be selected from the group consisting of a nitride layer, a TetraEthly OrthoSilicate (TEOS)-based layer, a low temperature oxide (LTO) layer, and an indium-tin oxide (ITO) layer.

As illustrated in FIG. 5F, the second microlens material layer 208 and the oxide layer 203 can be selectively removed to expose a predetermined portion of the metal pad 202 by using a photo and etching process such that the metal pad opening part 210 is formed.

The second microlens material layer 208 and the oxide layer 203 on the metal pad 202 are etched by using a dry etching process.

The second microlens material layer 208 remaining on the unit pixel region of the semiconductor substrate 200 becomes the second microlens 209.

According to the present invention, a CMOS image sensor and a method of fabricating the same provide the following advantages.

First, the ability of concentrating light increases by removing gaps between microlenses. Therefore, the ability of displaying an image can be improved even though the chip size is reduced.

Second, the metal pad is not contaminated by performing an opening process of the metal pad after a final process of an image sensor, which is identical to a general logic process. Therefore, the corrosion of the metal pad can be prevented to improve reliability and yield of the image sensor.

It will be apparent to those skilled in the art that various modifications and variations can be made in the present invention. Thus, it is intended that the present invention covers the modifications and variations of this invention provided they come within the scope of the appended claims and their equivalents.

1. A CMOS (complementary metal oxide semiconductor) image sensor comprising:
a substrate having a unit pixel region and a pad region;
a metal pad formed on the pad region of the substrate;
an insulation layer formed on an entire surface of the substrate, wherein the insulation layer has a metal pad opening part that exposes a predetermined portion of the metal pad;
a plurality of first microlenses formed spaced apart a predetermined distance above the insulation layer in the unit pixel region; and
a plurality of second microlenses formed on an entire surface of the unit pixel region including the plurality of first microlenses.

2. The CMOS image sensor according to claim 1, wherein the plurality of first microlenses are formed of a nitride layer.

3. The CMOS image sensor according to claim 1, wherein the plurality of second microlenses are formed of a material selected from the group consisting of a nitride layer, a TEOS (TetraEthly OrthoSilicate)-based layer, and an LTO (low temperature oxide) layer.

4. The CMOS image sensor according to claim 1, wherein the second microlens is formed at a thickness that is half the predetermined distance between adjacent first microlenses.

5. A method of fabricating a CMOS image sensor, the method comprising:
forming a metal pad on a pad region of a substrate, the substrate having a unit pixel region and the pad region;
forming an insulation layer on an entire surface of the substrate including the metal pad;
forming a first microlens material layer above the insulation layer;
forming sacrificial microlenses on the first microlens material layer in the unit pixel region;
etching the sacrificial microlenses and the first microlens material layer to form a plurality of first microlenses above the insulation layer in the unit pixel region;
forming a second microlens material layer on an entire surface of the substrate including the first microlens; and
selectively removing the second microlens material layer and the insulation layer to expose a predetermined portion of the metal pad such that a metal pad opening part is formed.

6. The method of claim 5, wherein etching the sacrificial microlenses and the first microlens material layer comprises maintaining an etching selectivity of the sacrificial microlens and the first microlens material layer at 1:1.

7. The method of claim 5, wherein the first microlens material layer is formed of a nitride layer.

8. The method of claim 5, wherein the second microlens is formed of a material selected from the group consisting of a nitride layer, a TEOS-based layer, and an LTO layer.

9. The method of claim 5, further comprising forming a nitride layer for planarization below the first microlens material layer.

10. The method of claim 5, wherein the first microlens material layer is formed at a thickness of 1000 to 4000 Å.

11. The method of claim 5, wherein the second microlens material layer is formed at a thickness that is half of a distance between adjacent first microlenses.
